(19) United States
(12) Patent Application Publication
(10) Pub. No.: US 2025/0351465 A1
(43) Pub. Date: Nov. 13, 2025

(54) SEMICONDUCTOR DEVICE AND METHOD FOR FABRICATING THE SAME

(71) Applicant: Samsung Electronics Co., Ltd., Suwon-si (KR)

(72) Inventors: Ki Joon Kim, Suwon-si (KR); Wan Ki Kim, Suwon-si (KR)

(21) Appl. No.: 18/987,932

(22) Filed: Dec. 19, 2024

(30) Foreign Application Priority Data
May 7, 2024 (KR) 10-2024-0059888

(51) Int. Cl. H10D 30/69; H10B 51/30; H10D 62/10; H10D 64/66; H10D 64/68

(52) U.S. Cl. CPC H10D 30/701; H10D 62/126; H10D 64/667; H10D 64/689; H10D 64/693; H10B 51/30

(57) ABSTRACT

An semiconductor device includes a substrate, a stacked structure which includes a mold insulating film and a first conductive pattern alternately stacked on the substrate along a first direction intersecting an upper surface of the substrate, a conductive pillar which extends in the first direction and penetrates the stacked structure, a channel layer which is interposed between the first conductive pattern and the conductive pillar, a ferroelectric layer which is interposed between the channel layer and the conductive pillar, and includes hafnium nitride, and an interface layer which is interposed between the channel layer and the ferroelectric layer, and includes hafnium nitride, wherein the ferroelectric layer includes a first side surface opposite to the channel layer and a second side surface opposite to the conductive pillar, and N/Hf of the ferroelectric layer on the first side surface is smaller than N/Hf of the ferroelectric layer on the second side surface.

REFERENCE TO PRIORITY APPLICATION

This application claims priority to Korean Patent Application No. 10-2024-0059888, filed May 7, 2024, the disclosure of which is hereby incorporated herein by reference.

### BACKGROUND

The present disclosure relates to semiconductor devices and methods of fabricating the same. More specifically, the present disclosure relates to integrated circuit memory devices and methods of fabricating the same.

Ferroelectrics are materials having ferroelectricity in which an internal electric dipole moment is aligned to maintain spontaneous polarization even when no external electric field is applied. In addition, the polarization of the ferroelectrics may be changed by applying an external electric field equal to or greater than a coercive field, and the status thereof can be electrically read through changes in materials such as adjacent metals and semiconductors. Therefore, research for improving performance by applying the characteristics of such ferroelectrics to semiconductor devices is ongoing.

Meanwhile, as the ferroelectricity of hafnium-based nitride has been discovered, a ferroelectric field effect transistor (FeFET) using the hafnium-based nitride is being researched.

### SUMMARY

Aspects of the present disclosure provide a semiconductor device having improved performance, and a method of fabricating a semiconductor device having improved performance.

However, aspects of the present disclosure are not restricted to the ones set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device that includes: a substrate, a stacked structure including a mold insulating film and a first conductive pattern alternately stacked on the substrate along a first direction intersecting an upper surface of the substrate, a conductive pillar that extends in the first direction and penetrates the stacked structure, a channel layer that extends between the first conductive pattern and the conductive pillar, a ferroelectric layer that extends between the channel layer and the conductive pillar, and an interface layer that extends between the channel layer and the ferroelectric layer. Both the ferroelectric layer and interface layer may include hafnium nitride. According to some embodiments, the ferroelectric layer may include a first side surface opposite to the channel layer and a second side surface opposite to the conductive pillar, and a nitrogen-to-hafnium (N/Hf) atomic ratio of the ferroelectric layer on the first side surface may be smaller than the N/Hf atomic ratio of the ferroelectric layer on the second side surface.

According to another aspect of the present disclosure, there is provided a semiconductor device that includes: a substrate, a stacked structure defined by a mold insulating film and a first conductive pattern alternately stacked on the substrate along a first direction intersecting an upper surface of the substrate, a conductive pillar, which extends in the first direction and penetrates the stacked structure, a channel layer, which extends between the first conductive pattern and the conductive pillar, a ferroelectric layer extending between the channel layer and the conductive pillar, an interfacial layer extending between the channel layer and the ferroelectric layer, and a gate dielectric layer extending between the conductive pillar and the ferroelectric layer. According to some embodiments, the ferroelectric layer, the interfacial layer and the gate dielectric layer include hafnium nitride, and a nitrogen-to-hafnium (N/Hf) atomic ratio of the interfacial layer is smaller than the N/Hf atomic ratio of the gate dielectric layer.

According to a further aspect of the present disclosure, a semiconductor device is provided that includes: a substrate, a plurality of first conductive patterns on the substrate, which are spaced apart from each other in a first direction intersecting an upper surface of the substrate, and extend in a second direction intersecting the first direction, and a plurality of second conductive patterns on the substrate, which are spaced apart from each other in the first direction, and extend in the second direction, but are spaced apart from the plurality of first conductive patterns in a third direction intersecting the first direction and the second direction. A conductive pillar is provided, which extends in the first direction between the plurality of first conductive patterns and the plurality of second conductive patterns. A plurality of channel layers is provided on the side surfaces of the conductive pillars, which connect the plurality of first conductive patterns and the plurality of second conductive patterns. A ferroelectric layer is provided, which extends between the conductive pillar and each of the channel layers, and includes hafnium nitride. And, an interface layer is provided, which extends between each of the channel layers and the ferroelectric layers, and includes hafnium nitride. The ferroelectric layer includes a first side surface opposite to the interface layer and a second side surface opposite to the conductive pillar; and, a nitrogen-to-hafnium (N/Hf) atomic ratio of the ferroelectric layer on the first side surface is smaller than the N/Hf atomic ratio of the ferroelectric layer on the second side surface.

According to another aspect of the present disclosure, an integrated circuit memory device is provided with a vertically-integrated plurality of memory cells that share a gate electrode pillar, which extends normal to an underlying substrate. The plurality of memory cells respectively include a channel layer, and a ferroelectric layer extending between the channel layer and the gate electrode pillar; the ferroelectric layer includes a first hafnium nitride region extending opposite the channel layer, and a second hafnium nitride region extending opposite the gate electrode pillar. Moreover, according to an embodiment, the first hafnium nitride region has a first nitrogen-to-hafnium (N/Hf) atomic ratio therein, and the second hafnium nitride region has a second N/Hf atomic ratio therein that is greater than the first N/Hf atomic ratio. In addition, the memory device may further include an interface layer, which includes hafnium nitride and extends between the channel layer and the ferroelectric layer, which may include hafnium nitride as HfN_{w}, where 1.05≤w≤1.5.

According an additional aspect of the present disclosure, a non-volatile memory cell includes: a substrate having a gate electrode thereon, a channel region extending opposite the gate electrode, and a ferroelectric region extending between the channel region and the gate electrode; the ferroelectric region includes a first hafnium nitride region extending opposite the channel region, and a second hafnium nitride region extending opposite the gate electrode. In addition, a gate dielectric layer is provided, which extends between the gate electrode and the ferroelectric region. According to some embodiments, the first hafnium nitride region has a first nitrogen-to-hafnium (N/Hf) atomic ratio therein, and the second hafnium nitride region has a second N/Hf atomic ratio therein that is greater than the first N/Hf atomic ratio.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail illustrative embodiments thereof with reference to the attached drawings, in which:

FIG. 1 is a perspective view for explaining a semiconductor device according to some embodiments.

FIG. 2 is an enlarged view for explaining a region R1 of FIG. 1.

FIG. 3 is an enlarged view for explaining a region R2 of FIG. 2.

FIG. 4 is a graph for explaining a change in nitrogen-to-hafnium (N/Hf) atomic ratio along P1 to P2 of FIG. 3.

FIGS. 5A to 5C are various enlarged views for explaining a region R2 of FIG. 2.

FIGS. 6 to 9 are various other enlarged views for explaining the region R1 of FIG. 1.

FIGS. 10 to 18 are intermediate stage diagrams for describing methods for fabricating semiconductor devices according to some embodiments.

### DETAILED DESCRIPTION OF THE EMBODIMENTS

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure. Further, in this specification, the term “same” means not only exactly the same thing, but also includes minute differences that may occur due to a process margin or the like.

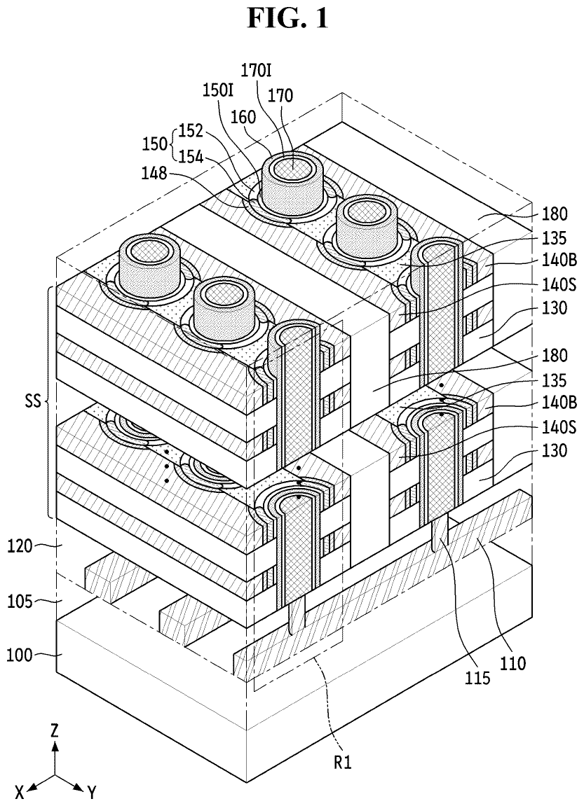

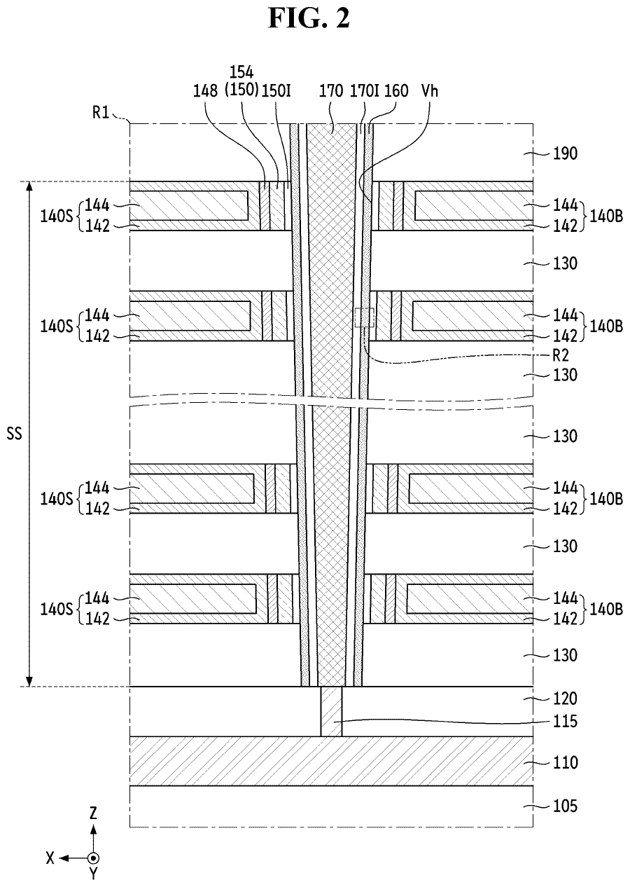

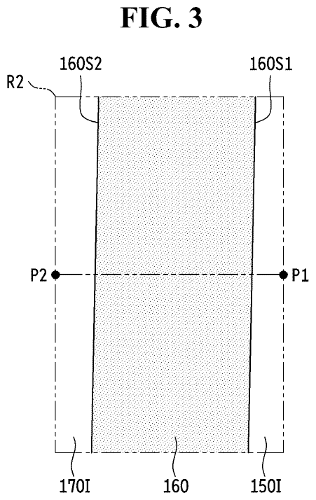

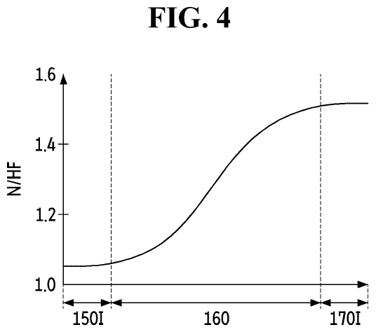

Hereinafter, a semiconductor device according to exemplary embodiments will be described with reference to FIGS. 1 to 9. FIG. 1 is a perspective view for explaining a semiconductor device according to some embodiments. FIG. 2 is an enlarged view for explaining a region R1 of FIG. 1. FIG. 3 is an enlarged view for explaining a region R2 of FIG. 2. FIG. 4 is a graph for explaining a change in a N/Hf atomic ratio along P1 to P2 of FIG. 3.

Referring to FIGS. 1 and 2, the semiconductor device according to some embodiments includes a substrate 100, a lower structure 105, a wiring pattern 110, a stacked structure SS, a channel layer 150, an interface layer 1501, a ferroelectric layer 160, a gate dielectric layer 1701, a conductive pillar 170, and a cutting pattern 180. The substrate 100 may be bulk silicon or silicon-on-insulator (SOI). The substrate 100 may be a silicon substrate or may include other materials, for example, silicon germanium, gallium arsenide, silicon germanium-on-insulator (SGOI), indium antimonide, lead telluride, indium arsenide, indium phosphide, gallium arsenide or gallium antimonide. Alternatively, the substrate 100 may be a base substrate on which an epitaxial layer is formed, or may be a ceramic substrate, a quartz substrate, a glass substrate for a display, or the like.

The lower structure 105 may be disposed on the substrate 100. The lower structure 105 may include a peripheral circuit (not shown) formed on the substrate 100. For example, the lower structure 105 may include the peripheral circuit, a multi-layer wiring layer electrically connected to the peripheral circuit, and an insulating layer that covers the peripheral circuit and the wiring layer. The peripheral circuit may constitute a circuit that controls the operation of the semiconductor device formed on the substrate 100 and the lower structure 105. The peripheral circuit may include not only various active elements such as a transistor, but also various passive elements such as a capacitor, a resistor or an inductor.

The wiring pattern 110 may be disposed on the lower structure 105. For example, the wiring pattern 110 may extend along an upper surface of the lower structure 105. In some embodiments, the plurality of wiring patterns 110 may be two-dimensionally arranged on a plane (e.g., an XY plane) parallel to an upper surface of the substrate 100. For example, the wiring patterns 110 may extend long in a first direction X and be spaced apart from each other in a second direction Y intersecting the first direction X. In some embodiments, the wiring pattern 110 may be provided as a word line of a semiconductor memory device.

The stacked structure SS may be formed on the wiring pattern 110. For example, a base insulating layer 120 that covers the wiring pattern 110 may be formed. A stacked structure SS may be formed on the upper surface of the base insulating layer 120. The stacked structure SS may include a mold insulating layer 130, a mold sacrificial layer 135, a first conductive pattern 140S, and a second conductive pattern 140B. The mold insulating layer 130 and the mold sacrificial layer 135 may be stacked alternately along a vertical direction (e.g., a third direction Z intersecting the first direction X and the second direction Y) that intersects the upper surface of the substrate 100.

The mold insulating layer 130 and the mold sacrificial layer 135 may each be a layered structure extending parallel to the upper surface of the substrate 100. The mold insulating layer 130 and the mold sacrificial layer 135 may each include an insulating material, for example, but not limited to, at least one of silicon oxide, silicon nitride or silicon oxynitride. The mold sacrificial layer 135 may include a material having an etching selectivity with respect to the mold insulating layer 130. As an example, the mold insulating layer 130 may include a silicon oxide film, and the mold sacrificial layer 135 may include a silicon nitride film.

The first conductive pattern 140S may be alternately stacked with the mold insulating layer 130 along the third direction Z. A plurality of first conductive patterns 140S arranged along the third direction Z may be sequentially stacked while being spaced apart from each other by the mold insulating layer 130. The first conductive pattern 140S may be disposed at the same level as the mold sacrificial layer 135. For example, on the basis of the upper surface of the substrate 100, the first conductive pattern 140S and the mold sacrificial layer 135 may be located at the same height. In some embodiments, the first conductive pattern 140S may be provided as a source line of the semiconductor memory device.

The second conductive pattern 140B may be alternately stacked with the mold insulating layer 130 along the third direction Z. A plurality of second conductive patterns 140B arranged along the third direction Z may be sequentially stacked while being spaced apart from each other by the mold insulating layer 130. The second conductive pattern 140B may be disposed at the same level as the mold sacrificial layer 135. For example, on the basis of the upper surface of the substrate 100, the second conductive pattern 140B and the mold sacrificial layer 135 may be located at the same height. In some embodiments, the second conductive pattern 140B may be provided as a bit line of a semiconductor memory device.

The first conductive pattern 140S and the second conductive pattern 140B may extend in parallel in the second direction Y. That is, the first conductive pattern 140S and the second conductive pattern 140B may each extend long in the second direction Y and be spaced apart from each other in the first direction X. The mold sacrificial layer 135 may be interposed between the first conductive pattern 140S and the second conductive pattern 140B. The first conductive pattern 140S and the second conductive pattern 140B may be separated in the first direction X by the mold sacrificial layer 135.

The first conductive pattern 140S and the second conductive pattern 140B may include, for example, but not limited to, a metal such as tungsten (W), molybdenum (Mo), ruthenium (Ru), cobalt (Co), and nickel (Ni) and a semiconductor material such as silicon. In some embodiments, as shown in FIG. 2, each of the first conductive pattern 140S and the second conductive pattern 140B may include a barrier conductive film 142 and a filling metal film 144 that are stacked in sequence. The barrier conductive film 142 may include a metal or a metal nitride for preventing the diffusion of a metal element included in the filling metal film 144. For example, the barrier conductive film 142 may include at least one of titanium (Ti), tantalum (Ta), tungsten (W), nickel (Ni), cobalt (Co), platinum (Pt), an alloy thereof or a nitride thereof. The filling metal film 144 may fill a region of the first conductive pattern 140S and/or a region of the second conductive pattern 140B that remains after the barrier conductive film 142 is filled. The filling metal film 144 may include a conductive metal, for example, at least one of tungsten (W), molybdenum (Mo) or ruthenium (Ru).

The conductive pillar 170 may extend in the third direction Z and penetrate the stacked structure SS. The conductive pillar 170 may intersect the plurality of first conductive patterns 140S arranged along the third direction Z and the plurality of second conductive patterns 140B arranged along the third direction Z. For example, the conductive pillar 170 may be interposed between the plurality of first conductive patterns 140S and the plurality of second conductive patterns 140B in the first direction X. In some embodiments, a plurality of conductive pillars 170 arranged along the second direction Y may be arranged between the first conductive pattern 140S and the second conductive pattern 140B. In some embodiments, the conductive pillar 170 may be provided as a gate electrode of a ferroelectric field effect transistor (FeFET) including the ferroelectric layer 160.

The conductive pillar 170 (e.g., vertical gate electrode) may be connected to the wiring pattern 110. For example, a contact 115 that penetrates the base insulating layer 120 to connect the wiring pattern 110 and the conductive pillar 170 may be formed. The conductive pillar 170 may be electrically connected to the wiring pattern 110 through the contact 115. In some embodiments, a plurality of conductive pillars 170 arranged along the first direction X may be commonly connected to one wiring pattern 110. From a planar viewpoint (e.g., an XY plane), the plurality of conductive pillars 170 are shown to be arranged in the form of a lattice, but this is merely an example. In some embodiments, unlike the shown example, the conductive pillars 170 may be arranged in various other forms, such as a honeycomb form.

Further, the wiring pattern 110 is only shown to be disposed on a lower face of the conductive pillar 170, but this is merely an example, and the wiring pattern 110 may be disposed on the upper surface of the conductive pillar 170. Alternatively, for example, the wiring pattern 110 may be disposed on both the lower face and the upper surface of the conductive pillar 170.

The conductive pillar 170 may include, for example, but not limited to, a metal such as tungsten (W), molybdenum (Mo), ruthenium (Ru), cobalt (Co), and nickel (Ni) or a semiconductor material such as silicon. In some embodiments, the conductive pillar 170 may include hafnium-based nitride having enhanced conductivity. For example, the conductive pillar 170 may include HfN_{z} (here, z<1), which is known to exhibit conductivity. As an example, the conductive pillar 170 may include a Hf₂N layer. Such a conductive pillar 170 may improve productivity by simplifying the process of a ferroelectric field effect transistor (FeFET) that uses hafnium-based nitride as the ferroelectric layer 160.

The channel layer 150 may be interposed between the first conductive pattern 140S and the conductive pillar 170 and/or between the second conductive pattern 140B and the conductive pillar 170. The channel layer 150 may connect the first conductive pattern 140S and the second conductive pattern 140B. For example, from a planar viewpoint (e.g., the XY plane), the channel layer 150 may have a ring shape that conformally extends along a profile of an outer side surface of the conductive pillar 170.

The channel layer 150 may include silicon (Si) or germanium (Ge) which is an elemental semiconductor material. Alternatively, the channel layer 150 may include a compound semiconductor material, for example, a group IV-IV compound semiconductor or a group III-V compound semiconductor. The group IV-IV compound semiconductor may include, for example, a binary compound or a ternary compound including at least two or more of carbon (C), silicon (Si), germanium (Ge) and tin (Sn), or a compound obtained by doping these elements with a group IV element. The group III-V compound semiconductor may be, for example, at least one of a binary compound, a ternary compound or a quaternary compound formed by combining at least one of aluminum (Al), gallium (Ga) and indium (In) as a group III element with at least one of phosphorus (P), arsenic (As) and antimony (Sb) as a group V element.

Alternatively, the channel layer 150 may include a two-dimensional semiconductor material or an oxide semiconductor material. Such a channel layer 150 may improve the mobility and short channel effect (SCE), or the like, thereby improving the performance of the semiconductor memory device.

The two-dimensional semiconductor material may include, but not limited to, graphene, carbon nanotube, two-dimensional chalcogenide including chalcogen elements, or combinations thereof. The chalcogen elements are elements belonging to group 16 of the periodic table, and may include at least one of oxygen (O), sulfur (S), selenium (Se), tellurium (Te), polonium (Po), and livermorium (Lv).

As an example, the two-dimensional chalcogenide may include a two-dimensional chalcogenide in which a semiconductor element and a chalcogen element are combined. For example, the two-dimensional chalcogenide may include at least one of silicon sulfide (Si₂S₃), silicon selenide (Si₂Se₃), silicon telluride (Si₂Te₃), germanium sulfide (Ge₂S₃), germanium selenide (Ge₂Se₃), germanium telluride (Ge₂Se₃), and combinations thereof.

As another example, the two-dimensional chalcogenide may include a transition metal dichalcogenide (TMD). The transition metal dichalcogenide (TMD) may include, for example, a transition metal element of one of Mo, W, Nb, V, Ta, Ti, Zr, Hf, Tc, Re, Cu, Ga, In, Sn, Ge, and Pb, and a chalcogen element of one of S, Se, and Te.

The oxide semiconductor material may include, for example, but not limited to, at least one of zinc oxide (ZnO), tin oxide (SnO), copper oxide (CuO) or nickel oxide (NiO).

In some embodiments, the channel layer 150 may be alternately arranged with the mold insulating layer 130 along the third direction Z. The plurality of channel layers 150 arranged along the third direction Z may be spaced apart from each other by the mold insulating layer 130.

In some embodiments, the channel layer 150 may include a semiconductor layer 152 and an impurity region 154.

The semiconductor layer 152 may extend along the outer side surface of the conductive pillar 170 between the first conductive pattern 140S and the second conductive pattern 140B. The semiconductor layer 152 may include the elemental semiconductor material or the compound semiconductor material. As an example, the semiconductor layer 152 may include a polysilicon (poly-Si) layer. Alternatively, the semiconductor layer 152 may include a polysilicon (poly-Si) layer doped with impurities.

The impurity region 154 may be interposed between the semiconductor layer 152 and the first conductive pattern 140S and/or between the semiconductor layer 152 and the second conductive pattern 140B. The impurity region 154 may be formed by doping a part of the semiconductor layer 152 with impurities, or may include an epitaxial layer that is grown from the semiconductor layer 152. For example, the impurity region 154 may be formed by injecting impurities into a first portion of the semiconductor layer 152 adjacent to the first conductive pattern 140S and a second portion of the semiconductor layer 152 adjacent to the second conductive pattern 140B. As an example, the impurity region 154 may include an n-type impurity (e.g., phosphorus (P) or arsenic (As)).

In some embodiments, a silicide layer 148 may be formed between the first conductive pattern 140S and the channel layer 150 and/or between the second conductive pattern 140B and the channel layer 150. The silicide layer 148 may be formed by reacting silicon (Si) contained in the channel layer 150 with a metal element (e.g., a metal element contained in the first conductive pattern 140S and/or the second conductive pattern 140B). The silicide layer 148 may include, but not limited to, at least one of nickel silicide, cobalt silicide, tungsten silicide, titanium silicide, niobium silicide, tantalum silicide or a combination thereof.

The ferroelectric layer 160 may be interposed between the channel layer 150 and the conductive pillar 170. For example, from the planar viewpoint (e.g., the XY plane), the ferroelectric layer 160 may have a ring shape that conformally extends along the profile of the inner side surface of the channel layer 150 and the outer side surface of the conductive pillar 170.

The ferroelectric layer 160 may include hafnium-based nitride having ferroelectricity. Ferroelectricity means a property which has spontaneous polarization and has a direction of polarization changed by an external electric field. For example, the ferroelectric layer 160 may include at least one of hafnium nitride (HfN), hafnium oxynitride (HfON), hafnium carbonitride (HfCN), hafnium oxycarbonitride (HfOCN) or a combination thereof. In some embodiments, the ferroelectric layer 160 may include HfN_{w} (here, 1.05≤w≤1.5), which is known to be capable of exhibiting ferroelectricity.

In some embodiments, the ferroelectric layer 160 may extend in the third direction Z and penetrate the stacked structure SS. For example, a vertical hole Vh which extends in the third direction Z and penetrates the stacked structure SS may be formed inside the stacked structure SS. The ferroelectric layer 160 and the conductive pillar 170 may be sequentially stacked in the vertical hole Vh.

The interface layer 1501 may be interposed between the channel layer 150 and the ferroelectric layer 160. For example, from the planar viewpoint (e.g., in the XY plane), the interface layer 1501 may have a ring shape that conformally extends along the profile of the inner side surface of the channel layer 150 and the outer side surface of the ferroelectric layer 160. In some embodiments, the interface layer 1501 may be alternately arranged with the mold insulating layer 130 along the third direction Z. The plurality of interface layers 1501 arranged along the third direction Z may be spaced apart from each other by the mold insulating layer 130.

The interface layer 1501 may include an insulating material, for example, but not limited to, at least one of silicon oxide, silicon nitride, silicon oxynitride, silicon oxycarbide, silicon boronitride, silicon boron carbonitride, silicon oxycarbonitride, and a low-k material having a dielectric constant smaller than that of silicon oxide.

Alternatively, for example, the interface layer 1501 may include at least one of hafnium-based oxide, hafnium-based nitride, hafnium-based carbide, zirconium-based oxide, zirconium-based nitride, zirconium-based carbide or a combination thereof. For example, the interface layer 1501 may include at least one of hafnium oxide (HfO), hafnium nitride (HfN), hafnium oxynitride (HfON), hafnium carbonitride (HfCN), hafnium oxycarbonitride (HfOCN), zirconium oxide (ZrO), zirconium nitride (ZrN), zirconium oxynitride (ZrON), zirconium carbonitride (ZrCN), zirconium oxycarbonitride (ZrOCN) or a combination thereof.

In some embodiments, the interface layer 1501 may include hafnium-based nitride. For example, the interface layer 1501 may include at least one of hafnium nitride (HfN), hafnium oxynitride (HfON), hafnium carbonitride (HfCN), hafnium oxycarbonitride (HfOCN) or a combination thereof. The interface layer 1501 may be formed naturally during the formation of the ferroelectric layer 160 on the channel layer 150, or may be formed by being deposited on the channel layer 150. In some embodiments, the interface layer 1501 may include hafnium-based nitride including a relatively low concentration of nitrogen (N) atoms. For example, the interface layer 1501 may include HfNₐ (here, 1.05≤a≤1.15).

In some embodiments, the nitrogen (N) concentration of the hafnium-based nitride of the interface layer 1501 may be equal to or less than the nitrogen (N) concentration of the hafnium-based nitride of the ferroelectric layer 160. For example, the ferroelectric layer 160 may include HfN_{w} (here, 1.05≤w≤1.5), and the interfacial layer 1501 may include HfNₐ (here, 1.05≤a≤w).

In some embodiments, the interface layer 1501 may include a low concentration of oxygen (O) atoms or may not include oxygen (O) atoms. For example, the oxygen atomic concentration of the interface layer 1501 may be about 10 at % or less, about 5 at % or less, about 1 at % or less, or about 0.1 at % or less.

The gate dielectric layer 1701 may be interposed between the conductive pillar 170 and the ferroelectric layer 160. For example, from the planar viewpoint (e.g., in the XY plane), the gate dielectric layer 1701 may have a ring shape that conformally extends along the profile of the inner side surface of the ferroelectric layer 160 and the outer side surface of the conductive pillar 170. In some embodiments, the gate dielectric layer 1701 may extend in the third direction Z and penetrate the stacked structure SS. For example, the ferroelectric layer 160, the gate dielectric layer 1701, and the conductive pillar 170 may be stacked sequentially inside the vertical hole Vh.

The gate dielectric layer 1701 may include a dielectric material, for example, but not limited to, at least one of silicon oxide, silicon nitride, silicon oxynitride, and a high-k material having a dielectric constant larger than that of silicon oxide. Alternatively, for example, the gate dielectric layer 1701 may include at least one of hafnium-based oxide, hafnium-based nitride, hafnium-based carbide, zirconium-based oxide, zirconium-based nitride, zirconium-based carbide or a combination thereof. For example, the interface layer 1501 may include at least one of hafnium oxide (HfO), hafnium nitride (HfN), hafnium oxynitride (HfON), hafnium carbonitride (HfCN), hafnium oxycarbonitride (HfOCN), zirconium oxide (ZrO), zirconium nitride (ZrN), zirconium oxynitride (ZrON), zirconium carbonitride (ZrCN), zirconium oxycarbonitride (ZrOCN) or a combination thereof.

In some embodiments, the gate dielectric layer 1701 may include hafnium-based nitride. For example, the gate dielectric layer 1701 may include at least one of hafnium nitride (HfN), hafnium oxynitride (HfON), hafnium carbonitride (HfCN), hafnium oxycarbonitride (HfOCN) or a combination thereof. Such a gate dielectric layer 1701 may improve productivity by simplifying the process of a ferroelectric field effect transistor (FeFET) that uses hafnium-based nitride as the ferroelectric layer 160.

In some embodiments, the gate dielectric layer 1701 may include hafnium-based nitride including a relatively high concentration of nitrogen (N) atoms. For example, the gate dielectric layer 1701 may include HfN_{b} (here, 1.35≤b≤1.5). As an example, the gate dielectric layer 1701 may include a Hf₂N₃ layer.

In some embodiments, the nitrogen (N) concentration of the hafnium-based nitride of the gate dielectric layer 1701 may be equal to or greater than the nitrogen (N) concentration of the hafnium-based nitride of the ferroelectric layer 160. For example, the ferroelectric layer 160 may include HfN_{w} (here, 1.05≤w≤1.5), and the gate dielectric layer 1701 may include HfN_{b} (here, w≤b≤1.5). In some embodiments, the gate dielectric layer 1701 may be omitted. For example, unlike the shown example, the ferroelectric layer 160 may be in contact with the conductive pillar 170.

The cutting pattern 180 may extend long in the second direction Y and cut the stacked structure SS. The plurality of cutting patterns 180 may extend side by side in the second direction Y. The stacked structure SS may be divided by the plurality of cutting patterns 180 to form a plurality of memory cell blocks. The cutting pattern 180 may include an insulating material, for example, but not limited to, at least one of silicon oxide, silicon nitride, and/or silicon oxynitride. As an example, the cutting pattern 180 may include a silicon oxide film.

Referring to FIGS. 1 to 4, the ferroelectric layer 160 includes a first side surface 160S1 opposite to the channel layer 150, and a second side surface 160S2 opposite to the conductive pillar 170. For example, the first side surface 160S1 of the ferroelectric layer 160 may be in contact with the interface layer 1501, and the second side surface 160S2 of the ferroelectric layer 160 may be in contact with the gate dielectric layer 1701.

According to some embodiments, a nitrogen-to-hafnium (N/Hf) atomic ratio of the ferroelectric layer 160 on the first side surface 160S1 may be smaller than a N/Hf atomic ratio of the ferroelectric layer 160 on the second side surface 160S2. Here, “N/Hf” refers to a ratio of nitrogen (N) to hafnium (Hf). For example, one side of the ferroelectric layer 160 including the first side surface 160S1 may include HfNₓ (here, 1.05≤x), and the other side of the ferroelectric layer 160 including the second side surface 160S2 may include HfN_{y} (here, x<y≤1.5).

In some embodiments, the N/Hf atomic ratio of the interfacial layer 1501 may be smaller than the N/Hf atomic ratio of the gate dielectric layer 1701. For example, the interfacial layer 1501 may include HfNₐ (here, 1.05≤a≤1.15), and the gate dielectric layer 1701 may include HfN_{b} (here, 1.35≤b≤1.5). In some further embodiments, and as shown in FIG. 4, a N/Hf atomic ratio of the ferroelectric layer 160 may gradually increase from the first side surface 160S1 toward the second side surface 160S2 (or from the interface layer 1501 toward the gate dielectric layer 1701).

Research for improving performance by applying ferroelectricity to the semiconductor device is continued. In particular, as the ferroelectricity of hafnium-based nitrides is discovered, ferroelectric field effect transistor (FeFET) using hafnium-based nitrides is researched. However, an interface layer that may be formed in the process of forming a ferroelectric layer including hafnium-based nitride may provide a cause of degrading the performance of ferroelectric field effect transistor (FeFET). For example, in the process of forming the ferroelectric layer on the channel layer, an interface layer may naturally be formed between the channel layer and the ferroelectric layer. Such an interface layer may cause charge trapping and/or breakdown, or the like, thereby degrading the characteristics of the semiconductor device including the ferroelectric field effect transistor (FeFET), for example, durability (e.g., program/erase cycling endurance) and/or memory window.

In contrast, the semiconductor device according to some embodiments may have improved characteristics by including the ferroelectric layer 160 having a relatively low N/Hf atomic ratio in a region adjacent to the channel layer 150. Specifically, as described above, a N/Hf atomic ratio of the first side surface 160S1 adjacent to the channel layer 150 may be smaller than a N/Hf atomic ratio of the second side surface 160S2 adjacent to the conductive pillar 170. As a result, the interface layer 1501 formed between the channel layer 150 and the ferroelectric layer 160 may include hafnium-based nitride including a relatively low concentration of nitrogen (N) atoms, and thus may have a relatively low dielectric constant. Accordingly, a semiconductor device in which charge trapping and/or breakdown due to the interface layer 1501 are reduced, and characteristics such as durability and/or memory window are improved may be provided.

In addition, the semiconductor device according to some embodiments may have further improved characteristics by including the gate dielectric layer 1701. Specifically, as described above, the gate dielectric layer 1701 formed between the conductive pillar 170 and the ferroelectric layer 160 may include hafnium-based nitride including a relatively high concentration of nitrogen (N) atoms, and thus may have a relatively high dielectric constant. Accordingly, a semiconductor device in which a leakage current due to the gate electrode (e.g., the conductive pillar 170) is reduced, the memory window is improved, and characteristics are further improved may be provided.

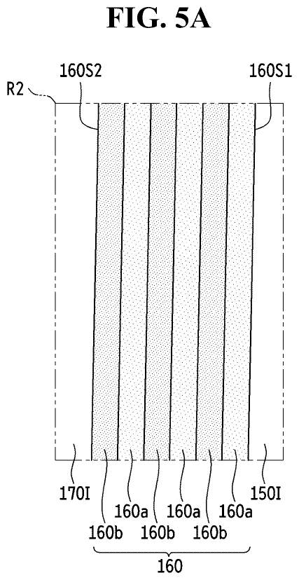

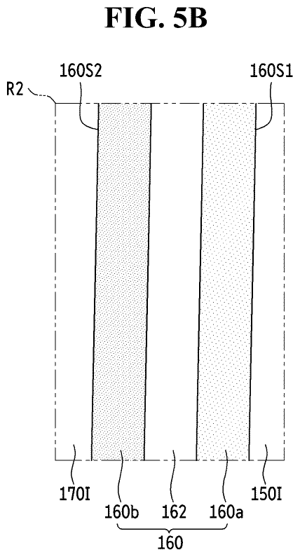

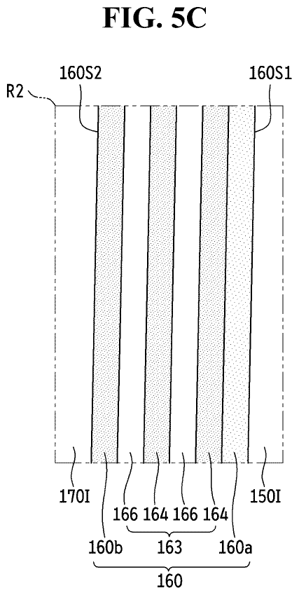

FIGS. 5A to 5C are various enlarged views for explaining a region R2 of FIG. 2. For convenience of explanation, repeated parts of contents explained above using FIGS. 1 to 4 will be briefly explained or omitted. Referring to FIGS. 1, 2, and 5A, in the semiconductor device according to some embodiments, the ferroelectric layer 160 includes a first sublayer 160a and a second sublayer 160b.

The first sublayer 160a and the second sublayer 160b may each include hafnium-based nitride having ferroelectricity. A N/Hf atomic ratio of the first sublayer 160a may be smaller than a N/Hf atomic ratio of the second sublayer 160b. For example, the first sublayer 160a may include HfNₓ (here, 1.05≤x), and the second sublayer 160b may include HfN_{y} (here, x<y≤1.5).

In some embodiments, the first sublayer 160a and the second sublayer 160b may be alternately stacked between the interface layer 1501 and the gate dielectric layer 1701, as shown in FIG. 5A. The plurality of first sublayers 160a and the plurality of second sublayers 160b that are alternately stacked may form a nanolaminate which is a composite material formed by stacking thin layers of different materials.

A thickness of the nanolaminate may be, for example, about 0.5 nm to about 20 nm. In the nanolaminate, the thickness of each first sublayer 160a and the thickness of each second sublayer 160b may be, for example, about 0.1 nm to 10 nm. In FIG. 5A, although the number of stacked first sublayers 160a and the number of stacked second sublayers 160b are shown to be three, this is merely exemplary, and it goes without saying that the number of stacked first sublayers 160a and the number of stacked second sublayers 160b may vary.

In some embodiments, the first sublayer 160a closest to the interface layer 1501 among the plurality of first sublayers 160a may be in contact with the interface layer 1501. For example, the first side surface 160S1 may be defined by the first sublayer 160a. In some embodiments, the second sublayer 160b closest to the gate dielectric layer 1701 among the plurality of second sublayers 160b may be in contact with the gate dielectric layer 1701. For example, the second side surface 160S2 may be defined by the second sublayer 160b. In some embodiments, the first sublayer 160a may include HfNₓ (here, 1.05≤x≤1.15), and the second sublayer 160b may include HfN_{y} (here, 1.25≤y≤1.35). As an example, the ferroelectric layer 160 may include a nanolaminate in which HfN_{1.1} and HfN_{1.3} are alternately stacked.

Referring to FIGS. 1, 2, and 5B, in the semiconductor device according to some embodiments, the ferroelectric layer 160 includes a first sublayer 160a, a second sublayer 160b, and a third sublayer 162. The first sublayer 160a and the second sublayer 160b may each include hafnium-based nitride having ferroelectricity. A N/Hf atomic ratio of the first sublayer 160a may be smaller than a N/Hf atomic ratio of the second sublayer 160b. For example, the first sublayer 160a may include HfNₓ (here, 1.05≤x≤1.15), and the second sublayer 160b may include HfN_{y} (here, x<y≤1.5). In some embodiments, the first sublayer 160a may be in contact with the interface layer 1501. In some embodiments, the second sublayer 160b may be in contact with the gate dielectric layer 1701. In some embodiments, the first sublayer 160a may include HfNₓ(here, 1.05≤x≤1.15), and the second sublayer 160b may include HfN_{y} (here, 1.35≤y≤1.5). In some embodiments, the first sublayer 160a and the second sublayer 160b may each include hafnium-based nitride that includes a relatively high concentration of nitrogen (N) atoms. For example, the first sublayer 160a may include HfNₓ (here, 1.3≤x), and the second sublayer 160b may include HfN_{y} (here, x<y≤1.5). In some embodiments, the first sublayer 160a and the second sublayer 160b may each include a hafnium-based carbonitride. For example, the first sublayer 160a may include HfCNₓ (here, 1≤x), and the second sublayer 160b may include HfCN_{y} (here, x<y≤1.5).

The third sublayer 162 may be interposed between the first sublayer 160a and the second sublayer 160b. In some embodiments, the third sublayer 162 may be in contact with the first sublayer 160a and the second sublayer 160b. The third sublayer 162 may include at least one of hafnium-based oxide, hafnium-based nitride, zirconium-based oxide, zirconium-based nitride having ferroelectricity or a combination thereof. In some embodiments, the third sublayer 162 may include hafnium zirconium oxide (HZO) having ferroelectricity.

Referring to FIGS. 1, 2, and 5C, in the semiconductor device according to some embodiments, the ferroelectric layer 160 includes a first sublayer 160a, a second sublayer 160b, and a composite layer 163. The first sublayer 160a and the second sublayer 160b may each include hafnium-based nitride having ferroelectricity. A N/Hf atomic ratio of the first sublayer 160a may be smaller than a N/Hf atomic ratio of the second sublayer 160b. For example, the first sublayer 160a may include HfNₓ (here, 1.05≤x), and the second sublayer 160b may include HfN_{y} (here, x<y≤1.5). In some embodiments, the first sublayer 160a may be in contact with the interface layer 1501. In some embodiments, the second sublayer 160b may be in contact with the gate dielectric layer 1701. In some embodiments, the first sublayer 160a may include HfNₓ (here, 1.05≤x≤1.15), and the second sublayer 160b may include HfN_{y} (here, 1.35≤y≤1.5).

The composite layer 163 may be interposed between the first sublayer 160a and the second sublayer 160b. The composite layer 163 may include a fourth sublayer 164 and a fifth sublayer 166 that are alternately stacked between the first sublayer 160a and the second sublayer 160b. The plurality of fourth sublayers 164 and the plurality of fifth sublayers 166 that are alternately stacked may form a nanolaminate.

Each of the fourth sublayer 164 and the fifth sublayer 166 may include at least one of hafnium-based oxide, hafnium-based nitride, zirconium-based oxide, zirconium-based nitride having ferroelectricity or a combination thereof. For example, the fourth sublayer 164 may be any one of the first to third sublayers 160a, 160b, and 162 described above, and the fifth sublayer 166 may be any one of the first to third sublayers 160a, 160b, and 162 described above.

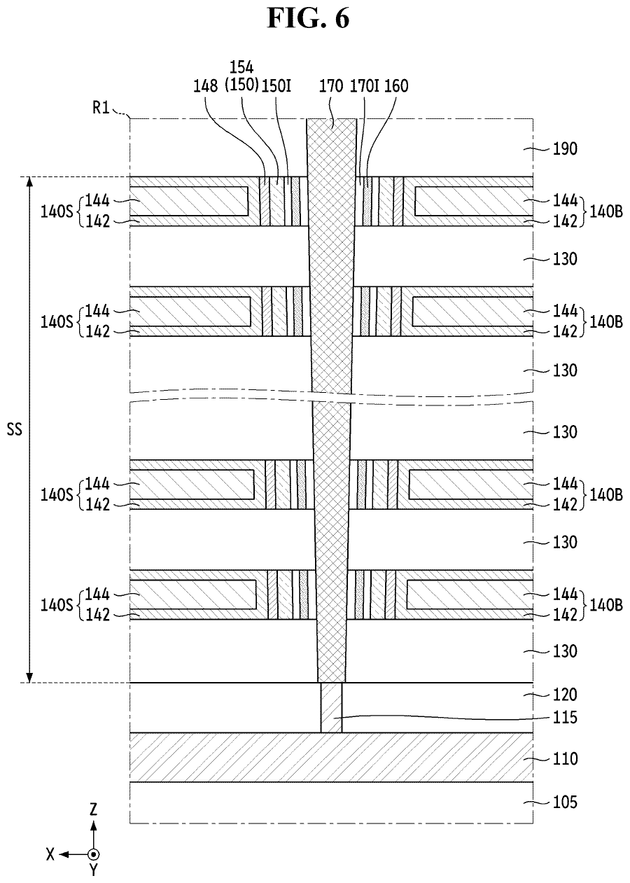

FIGS. 6 to 9 are various other enlarged views for explaining the region R1 of FIG. 1. For convenience of explanation, repeated parts of contents explained above using FIGS. 1 to 4 will be briefly explained or omitted. Referring to FIGS. 1 and 6, in the semiconductor device according to some embodiments, the ferroelectric layers 160 are arranged alternately with the mold insulating layers 130 along the third direction Z. The plurality of ferroelectric layers 160 arranged along the third direction Z may be spaced apart from each other by the mold insulating layers 130. In some embodiments, the gate dielectric layer 1701 may be arranged alternately with the mold insulating layers 130 along the third direction Z. The gate dielectric layers 1701 arranged along the third direction Z may be spaced apart from each other by the mold insulating layers 130.

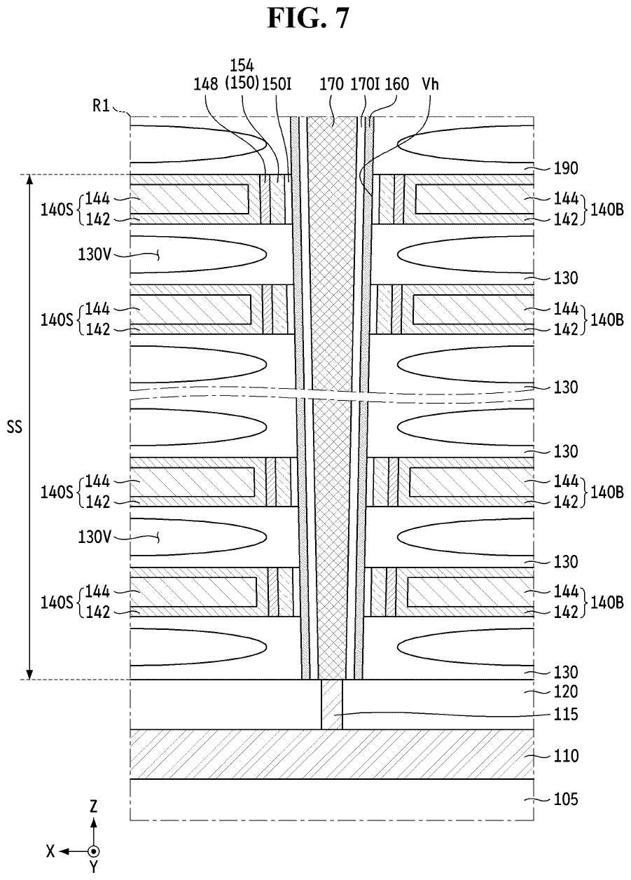

Referring to FIGS. 1 and 7, in the semiconductor device according to some embodiments, the mold insulating layer 130 includes a void 130V. The void 130V may be, for example, an air gap. The plurality of first conductive patterns 140S arranged along the third direction Z may be spaced apart from each other by the void 130V. The plurality of second conductive patterns 140B arranged along the third direction Z may be spaced apart from each other by the void 130V. Because the void 130V may have a lower dielectric constant than an insulating material such as a silicon oxide film, the performance of the semiconductor device may be improved by reducing disturbance between memory cells arranged along the third direction Z.

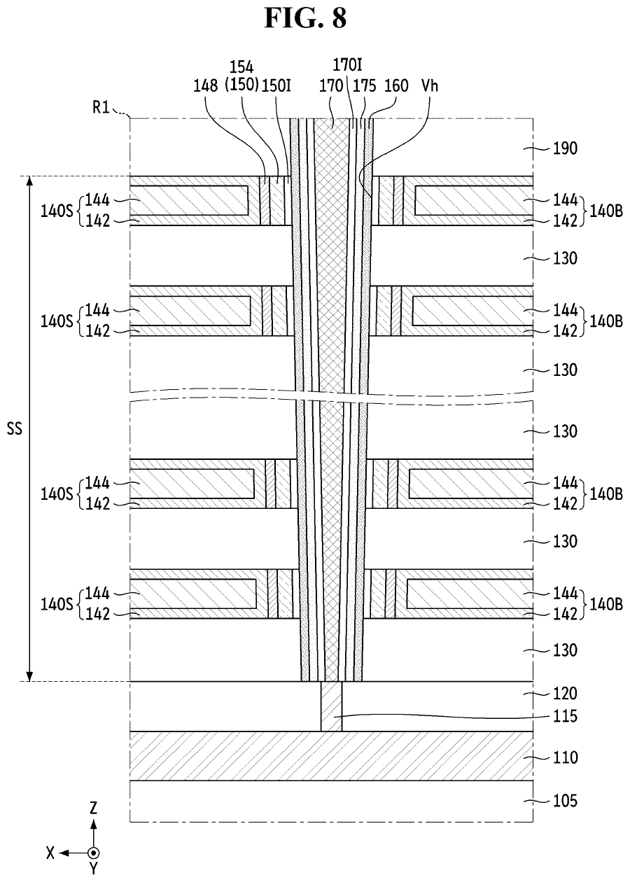

Referring to FIGS. 1 and 8, the semiconductor device according to some embodiments further includes a charge storage layer 175. The charge storage layer 175 may be interposed between the ferroelectric layer 160 and the gate dielectric layer 1701. The charge storage layer 175 may store data by trapping charges (e.g., electrons or holes). As an example, the charge storage layer 175 may include a silicon nitride film. In some embodiments, the charge storage layer 175 may extend in the third direction Z and penetrate the stacked structure SS. For example, the ferroelectric layer 160, the charge storage layer 175, the gate dielectric layer 1701, and the conductive pillar 170 may be stacked sequentially in the vertical hole Vh.

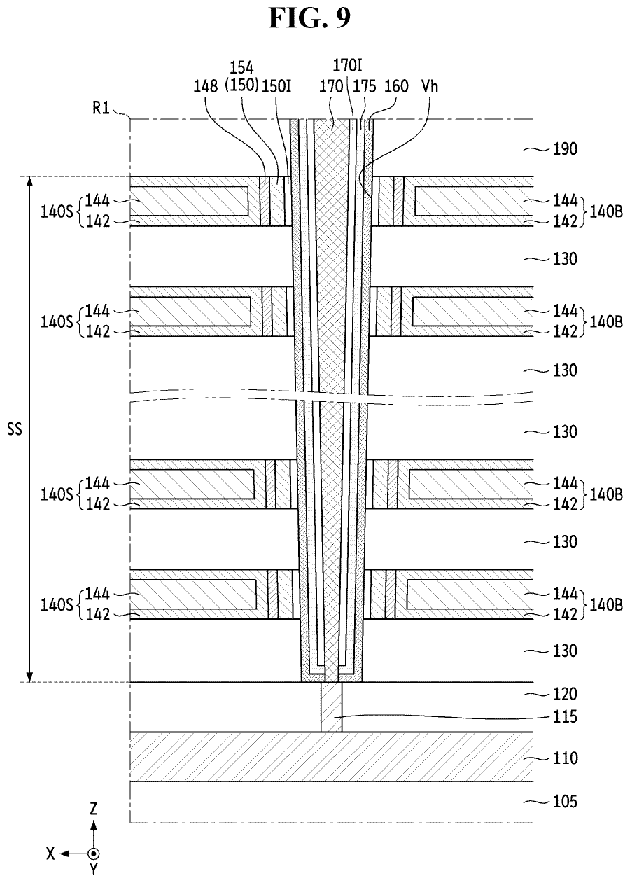

Referring to FIGS. 1 and 9, in the semiconductor device according to some embodiments, a part of the ferroelectric layer 160 extends along the upper surface of the base insulating layer 120. For example, a lower part of the ferroelectric layer 160 may have an “L” shape. The gate dielectric layer 1701 may extend along the upper surface and the inner side surface of the ferroelectric layer 160. The conductive pillar 170 penetrates the lower part of the gate dielectric layer 1701 and the lower part of the ferroelectric layer 160, and may be connected to the contact 115.

In some embodiments, the lower part of the charge storage layer 175 may have an “L” shape. The charge storage layer 175 may extend along the upper surface and the inner side surface of the ferroelectric layer 160. The conductive pillar 170 penetrates the lower part of the gate dielectric layer 1701, the lower part of the ferroelectric layer 160, and the lower part of the charge storage layer 175, and may be connected to the contact 115.

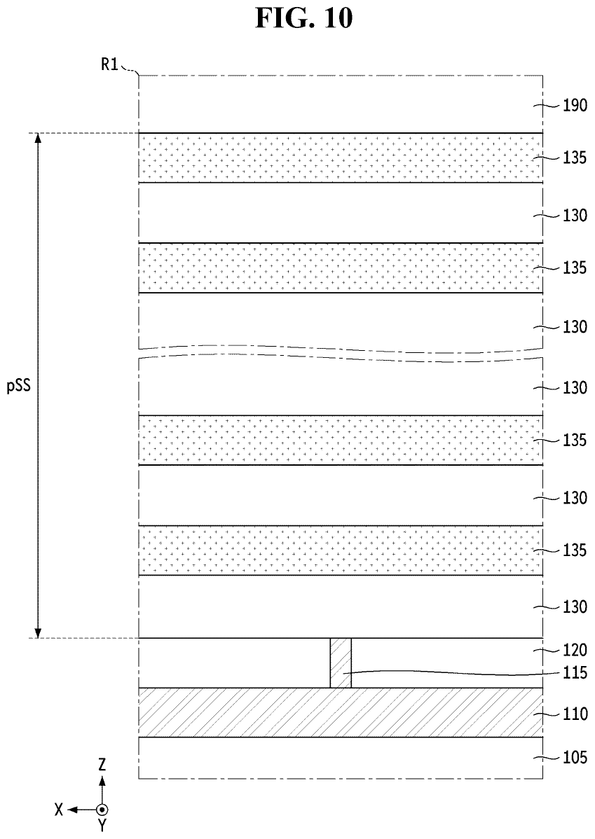

Hereinafter, a method for fabricating the semiconductor device according to exemplary embodiments will be described with reference to FIGS. 1 to 18. FIGS. 10 to 18 are intermediate stage diagrams for describing the method for fabricating the semiconductor device according to some embodiments. For convenience of description, repeated parts of contents explained above using FIGS. 1 to 9 will be briefly described or omitted.

Referring to FIG. 10, a mold structure pSS is formed. The mold structure pSS may include mold insulating layers 130 and mold sacrificial layers 135 that are alternately stacked along the third direction Z. The mold insulating layer 130 and the mold sacrificial layer 135 may each have a layered structure extending parallel to the upper surface of the substrate 100. The mold sacrificial layer 135 may include a material having an etching selectivity with respect to the mold insulating layer 130. As an example, the mold insulating layer 130 may include a silicon oxide film, and the mold sacrificial layer 135 may include a silicon nitride film.

In some embodiments, the wiring pattern 110 and the contact 115 may be formed before the mold structure pSS is formed. For example, the wiring pattern 110 may be formed on the lower structure 105, and a base insulating layer 120 that covers the wiring pattern 110 may be formed. Next, the contact 115 that penetrates the base insulating layer 120 and is connected to the wiring pattern 110 may be formed. The mold structure pSS may be formed on the base insulating layer 120.

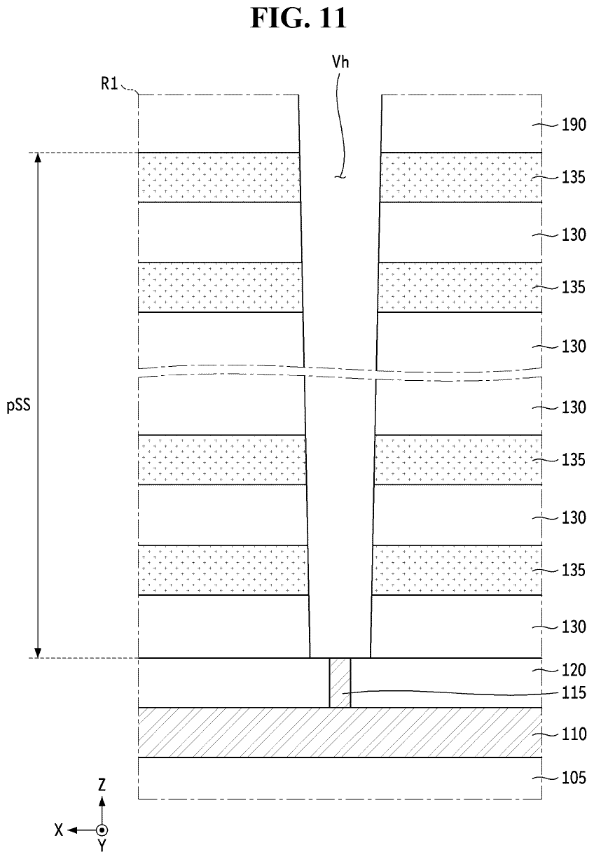

Referring to FIG. 11, the vertical hole Vh is formed inside the mold structure pSS. The vertical hole Vh may extend in the third direction Z and penetrate the mold structure pSS. The vertical hole Vh may expose the inner side surfaces of the plurality of mold insulating layers 130 and the inner side surfaces of the plurality of mold sacrificial layers 135. In some embodiments, the vertical holes Vh may expose the upper surface of the contact 115.

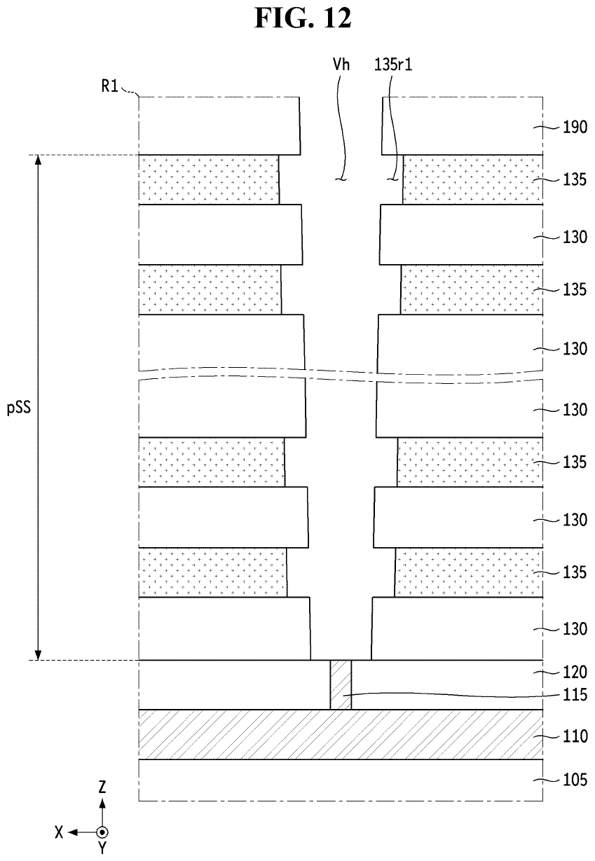

Referring to FIG. 12, a first recess process is performed on the mold sacrificial layer 135, using the vertical hole Vh. The mold sacrificial layer 135 may have an etching selectivity with respect to the mold insulating layer 130, and thus may be selectively recessed. As the first recess process is performed, a part of the mold sacrificial layer 135 exposed by the vertical hole Vh may be removed to form a first recess 135r1.

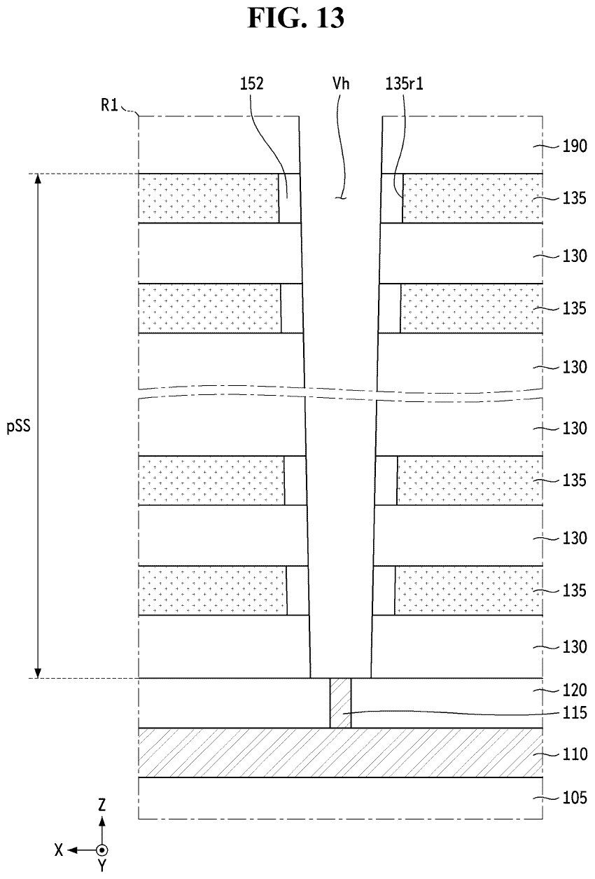

Referring to FIG. 13, a semiconductor layer 152 is formed inside the first recess 135r1. The semiconductor layer 152 may include the elemental semiconductor material or the compound semiconductor material. The plurality of semiconductor layers 152 arranged along the third direction Z may be spaced apart from each other by the mold insulating layer 130.

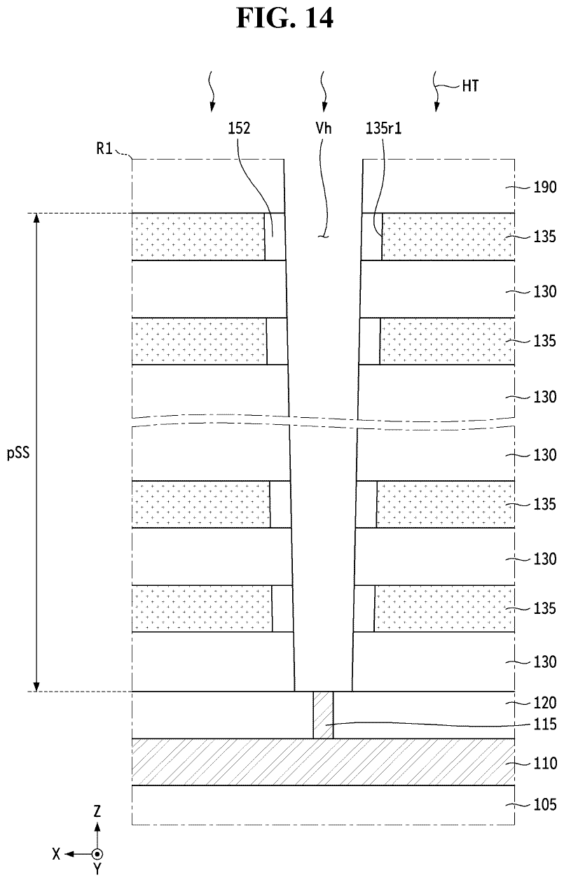

Referring to FIG. 14, a heat treatment process (HT) is performed on the semiconductor layer 152. The heat treatment process (HT) may include, but not limited to, an annealing process. As the heat treatment process (HT) is performed, crystallization of the semiconductor layer 152 may be induced or the properties of the material contained in the semiconductor layer 152 may be improved. As an example, when the semiconductor layer 152 includes a polysilicon (poly-Si) layer doped with impurities, the heat treatment process (HT) may improve the electrical properties of the semiconductor layer 152 by increasing the crystal grain size of the semiconductor layer 152 or activating the doped impurities.

In some embodiments, the heat treatment process (HT) may include an annealing process that uses hydrogen (H₂) and/or nitrogen (N₂). This heat treatment process (HT) may cure dangling bond on the surface of the semiconductor layer 152. As an example, when the semiconductor layer 152 includes a polysilicon (poly-Si) layer, hydrogen (H) atoms used in the heat treatment process (HT) may remove oxygen (O) atoms bonded to the surface of the semiconductor layer 152 to cure the dangling bonds.

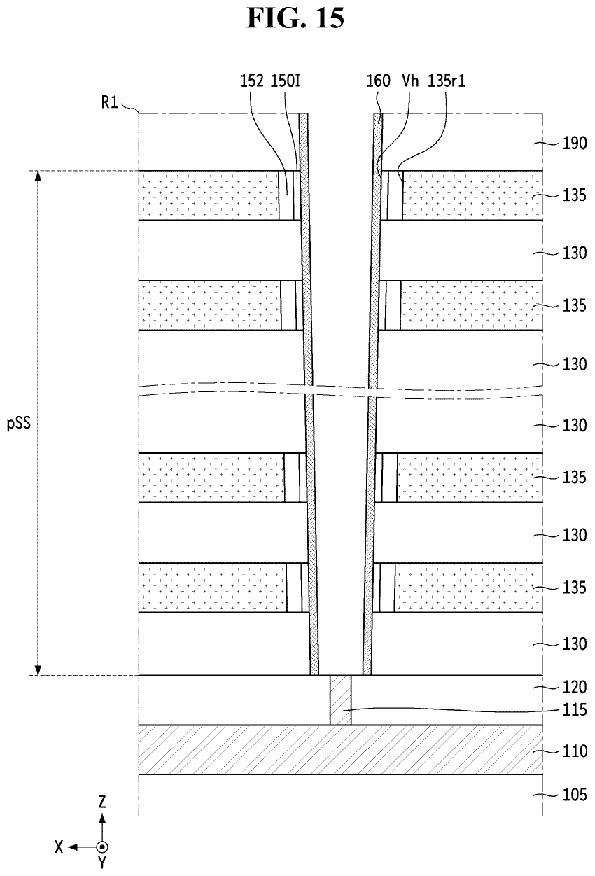

Referring to FIG. 15, the ferroelectric layer 160 is formed in the vertical hole Vh.

The ferroelectric layer 160 may extend along the side surface of the vertical hole Vh. The ferroelectric layer 160 may include hafnium-based nitride having ferroelectricity. For example, the ferroelectric layer 160 may include HfN_{w} (here, 1.05≤w≤1.5). In the process of forming the ferroelectric layer 160, the interface layer 1501 may be formed between the semiconductor layer 152 and the ferroelectric layer 160. In some embodiments, the interface layer 1501 may include hafnium-based nitride. In some embodiments, the interface layer 1501 may include hafnium-based nitride including a relatively low concentration of nitrogen (N) atoms. For example, the interface layer 1501 may include HfNₐ (here, 1.05≤a≤1.15).

In some embodiments, the ferroelectric layer 160 may be formed after the heat treatment process (HT) that uses hydrogen (H₂) and/or nitrogen (N₂) is performed. In this case, the interface layer 1501 may include a low concentration of oxygen (O) atoms or may not include oxygen (O) atoms. For example, the oxygen atomic concentration of the interface layer 1501 may be about 10 at % or less, about 5 at % or less, about 1 at % or less, or about 0.1 at % or less.

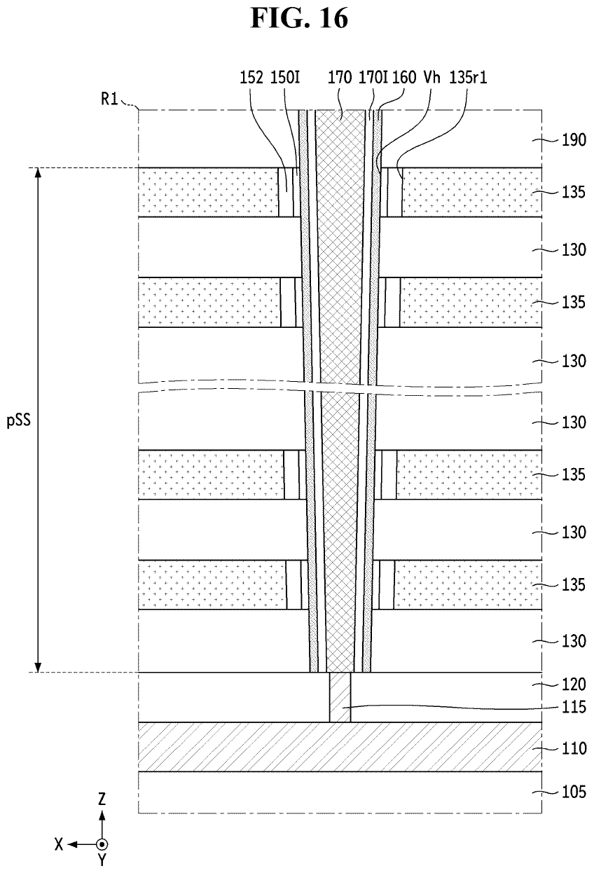

Referring to FIG. 16, the gate dielectric layer 1701 and the conductive pillar 170 are sequentially formed inside the vertical hole Vh. The gate dielectric layer 1701 may be formed on the ferroelectric layer 160. The gate dielectric layer 1701 may extend along the inner side surface of the ferroelectric layer 160. In some embodiments, the gate dielectric layer 1701 may include hafnium-based nitride. In some embodiments, the gate dielectric layer 1701 may include hafnium-based nitride including a relatively high concentration of nitrogen (N) atoms. For example, the gate dielectric layer 1701 may include HfN_{b} (here, 1.35≤b≤1.5).

The conductive pillar 170 may be formed on the gate dielectric layer 1701. The conductive pillar 170 may fill the region of the vertical hole Vh that is left after the ferroelectric layer 160 and the gate dielectric layer 1701 are filled. In some embodiments, the conductive pillar 170 may penetrate the mold structure pSS and be connected to the contact 115. In some embodiments, the conductive pillar 170 may include hafnium-based nitride having conductivity. For example, the conductive pillar 170 may include HfN_{z} (here, z<1).

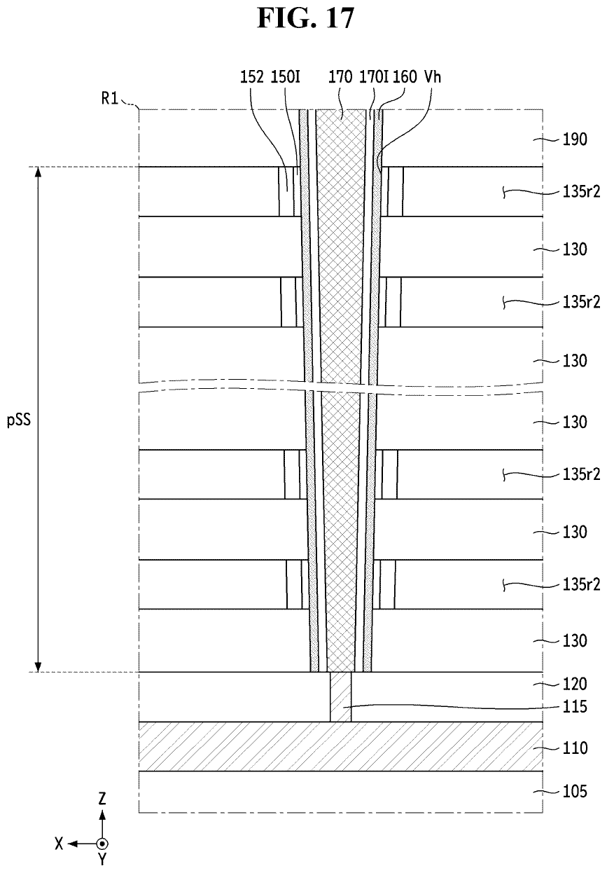

Referring to FIG. 17, a second recess process is performed on the mold sacrificial layer 135. For example, a cutting region (not shown) may be formed inside the mold structure pSS. The cutting region may extend long in the second direction Y to cut the mold structure pSS. A second recess process may then be performed on the mold sacrificial layer 135, using the cutting region. The mold sacrificial layer 135 may have an etching selectivity with respect to the mold insulating layer 130, and thus, may be selectively recessed. As the second recess process is performed, a part of the mold sacrificial layer 135 exposed by the cutting region may be removed to form a second recess 135r2.

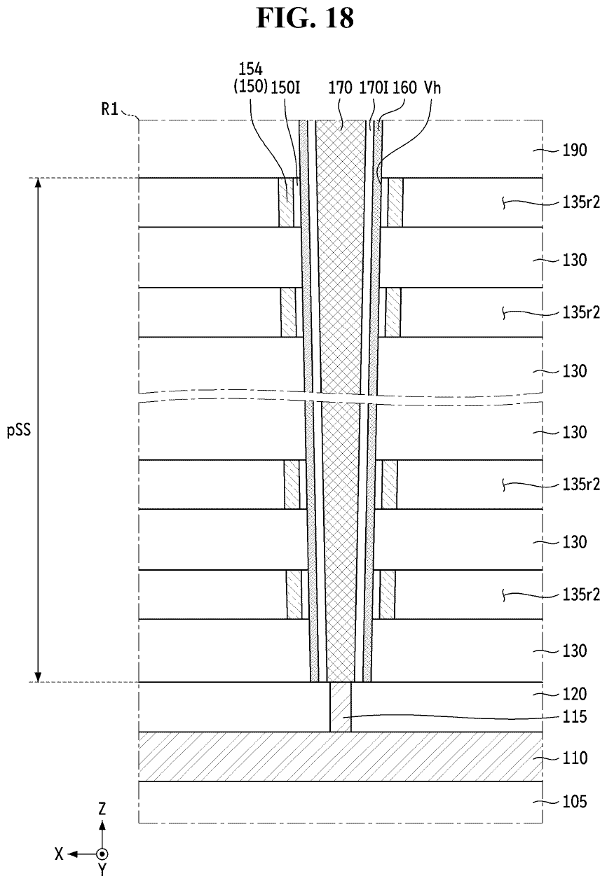

Referring to FIG. 18, an impurity region 154 is formed. For example, the channel layer 150 exposed by the second recess 135r2 may be doped with an impurity. As an example, the impurity region 154 may include an n-type impurity (e.g., phosphorus (P) or arsenic (As)). Accordingly, the channel layer 150 including the semiconductor layer 152 and the impurity region 154 may be provided.

Next, referring to FIGS. 1 and 2, the first conductive pattern 140S and the second conductive pattern 140B are formed inside the second recess 135r2. For example, the barrier conductive film 142 and the filling metal film 144 which are sequentially stacked may be formed inside the second recess 135r2. Accordingly, the stacked structure SS including the mold insulating layer 130, the mold sacrificial layer 135, the first conductive pattern 140S, and the second conductive pattern 140B may be provided. After forming the first conductive pattern 140S and the second conductive pattern 140B, the cutting pattern 180 may be formed. For example, an insulating material that fills the cutting region may be formed.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

1. A semiconductor device, comprising:
a substrate;
a stacked structure, which includes a mold insulating film and a first conductive pattern alternately stacked on the substrate along a first direction intersecting an upper surface of the substrate;
a conductive pillar, which extends in the first direction and penetrates the stacked structure;
a channel layer, which extends between the first conductive pattern and the conductive pillar;
a ferroelectric layer, which extends between the channel layer and the conductive pillar, and includes hafnium nitride; and
an interface layer, which extends between the channel layer and the ferroelectric layer, and includes hafnium nitride;
wherein the ferroelectric layer includes a first side surface opposite to the channel layer and a second side surface opposite to the conductive pillar; and
wherein a nitrogen-to-hafnium (N/Hf) atomic ratio of the ferroelectric layer on the first side surface is smaller than a N/Hf atomic ratio of the ferroelectric layer on the second side surface.

2. The semiconductor device of claim 1, wherein the ferroelectric layer includes HfN_{w}, where 1.05≤w≤1.5.

3. The semiconductor device of claim 2, wherein N/Hf of the ferroelectric layer gradually increases from the interface layer toward the conductive pillar.

4. The semiconductor device of claim 1,
wherein the ferroelectric layer includes first and second sublayers that are alternately stacked;
wherein the first sublayer includes HfNₓ, where 1.05≤x≤1.15; and
wherein the second sublayer includes HfN_{y}, where 1.25≤y≤1.35.

5. The semiconductor device of claim 1, wherein the interface layer includes HfNₐ, where 1.05≤a≤1.15.

6. The semiconductor device of claim 1, further comprising:
a gate dielectric layer, which extends between the conductive pillar and the ferroelectric layer, and includes hafnium nitride.

7. The semiconductor device of claim 6, wherein a N/Hf atomic ratio of the interface layer is smaller than a N/Hf atomic ratio of the gate dielectric layer.

8. The semiconductor device of claim 6, wherein the gate dielectric layer includes HfN_{b}, where 1.35≤b≤1.5.

9. The semiconductor device of claim 1, wherein the conductive pillar includes HfN_{z}, where z<1.

10. The semiconductor device of claim 1,
wherein the stacked structure further includes a second conductive pattern alternately stacked with the mold insulating film along the first direction;
wherein the first conductive pattern and the second conductive pattern each extend in a second direction intersecting the first direction, and are spaced apart from each other in a third direction intersecting the first direction and the second direction; and
wherein the channel layer connects the first conductive pattern and the second conductive pattern.

11. A semiconductor device comprising:
a substrate;
a stacked structure which includes a mold insulating film and a first conductive pattern alternately stacked on the substrate along a first direction intersecting an upper surface of the substrate;
a conductive pillar which extends in the first direction and penetrates the stacked structure;
a channel layer which is interposed between the first conductive pattern and the conductive pillar;
a ferroelectric layer which is interposed between the channel layer and the conductive pillar, and includes hafnium nitride;
an interfacial layer which is interposed between the channel layer and the ferroelectric layer, and includes hafnium nitride; and
a gate dielectric layer which is interposed between the conductive pillar and the ferroelectric layer, and includes hafnium nitride,
wherein a N/Hf atomic ratio of the interfacial layer is smaller than a N/Hf atomic ratio of the gate dielectric layer.

12. The semiconductor device of claim 11,
wherein the interfacial layer includes HfNₐ, where 1.05≤a≤1.15; and
wherein the gate dielectric layer includes HfN_{b}, where 1.35≤b≤1.5.

13. The semiconductor device of claim 11,
wherein the ferroelectric layer includes a first sublayer that is in contact with the interfacial layer, and a second sublayer that is in contact with the gate dielectric layer;
wherein the first sublayer includes HfNₓ, where 1.05≤x; and
wherein the second sublayer includes HfN_{y}, where x<y≤1.5.

14. The semiconductor device of claim 13, wherein the ferroelectric layer further includes a third sublayer interposed between the first sublayer and the second sublayer; and wherein the third sublayer includes hafnium zirconium oxide (HZO).

15. The semiconductor device of claim 11, further comprising:
a charge storage layer interposed between the conductive pillar and the ferroelectric layer.

16. The semiconductor device of claim 11,
wherein the stacked structure further includes a second conductive pattern alternately stacked with the mold insulating film along the first direction;
wherein the first conductive pattern and the second conductive pattern each extend in a second direction intersecting the first direction, and are spaced apart from each other in a third direction intersecting the first direction and the second direction; and
wherein the channel layer connects the first conductive pattern and the second conductive pattern.

17. A semiconductor device, comprising:
a substrate;
a plurality of first conductive patterns on the substrate, the first conductive patterns being spaced apart from each other in a first direction intersecting an upper surface of the substrate, and each extending in a second direction intersecting the first direction;
a plurality of second conductive patterns on the substrate, the second conductive patterns being spaced apart from each other in the first direction, each extending in the second direction, and being spaced apart from the plurality of first conductive patterns in a third direction intersecting the first direction and the second direction;
a conductive pillar which extends in the first direction between the plurality of first conductive patterns and the plurality of second conductive patterns;
a plurality of channel layers on the side surfaces of the conductive pillars, which connect the plurality of first conductive patterns and the plurality of second conductive patterns;
a ferroelectric layer which is interposed between the conductive pillar and each of the channel layers, and includes hafnium nitride; and
an interface layer which is interposed between each of the channel layers and the ferroelectric layers, and includes hafnium nitride;
wherein the ferroelectric layer includes a first side surface opposite to the interface layer and a second side surface opposite to the conductive pillar; and
wherein a N/Hf atomic ratio of the ferroelectric layer on the first side surface is smaller than a N/Hf atomic ratio of the ferroelectric layer on the second side surface.

18. The semiconductor device of claim 17, wherein the plurality of channel layers are spaced apart from each other in the first direction.

19. The semiconductor device of claim 17, wherein each of the channel layers has a ring shape extending along an outer side surface of the conductive pillar.

20. The semiconductor device of claim 17, further comprising:
a gate dielectric layer interposed between the conductive pillar and the ferroelectric layer and includes hafnium nitride; and
wherein a N/Hf atomic ratio of the interface layer is smaller than a N/Hf atomic ratio of the gate dielectric layer.

21.-31. (canceled)
